(19) United States
(12) Patent Application Publication
(10) Pub. No.: US 2018/0294947 A1
(43) Pub. Date: Oct. 11, 2018

(54) PHASE CALIBRATION METHOD AND ASSOCIATED PHASE LOCKED LOOP CIRCUIT

(71) Applicant: MStar Semiconductor, Inc., Hsinchu Hsien (TW)

(72) Inventors: Ting-Nan CHO, Hsinchu Hsien (TW); Kai-Wen CHENG, Hsinchu Hsein (TW); Tai-Lai TUNG, Hsinchu Hsien (TW)

(21) Appl. No.: 15/690,834

(22) Filed: Aug. 30, 2017

(30) Foreign Application Priority Data
Apr. 7, 2017 (TW) 106111627

(51) Int. Cl. H04L 7/033; H04L 7/04; H03L 7/08

(52) U.S. Cl. CPC H04L 7/0331; H03L 7/08; H04L 7/041

(57) ABSTRACT

A phase calibration method for a phase locked loop (PLL) circuit in a wireless communication device includes: calculating a header phase error of a header sub-frame of a frame in an input signal and a pilot phase error of a pilot sub-frame of the frame, wherein the header sub-frame and the pilot sub-frame are known data; generating an estimated phase error according to a relationship between the header phase error and the pilot phase error; generating a phase compensating signal according to the estimated phase error and a filtered signal; adjusting the input signal according to the phase compensating signal to generate a compensated input signal; detecting a phase error between a data sub-frame corresponding to the pilot sub-frame in the compensated input signal and a reference signal; and generating the filtered signal according to the phase error.

This application claims the benefit of Taiwan application Serial No. 106111627, filed Apr. 7, 2017 the subject matter of which is incorporated herein by reference.

### BACKGROUND OF THE INVENTION

### Field of the Invention

The invention relates to a phase calibration method and an associated phase locked loop (PLL) circuit, and more particularly, to a phase calibration method capable of estimating a phase error of unknown data in an input signal according to a relationship between calculated phase errors of known data in the input signal, and an associated PLL circuit.

### Description of the Related Art

A phase locked loop (PLL) circuit generates a periodic output signal, which is expected to have a fixed phase relationship with a periodic input signal. PLL circuits are extensively applied in various circuit systems, for example but not limited to, clock and data recovery circuits, transceivers and frequency synthesizers.

FIG. 1 shows a schematic diagram of a conventional PLL circuit 100. The PLL circuit 10 is for calibrating a phase error between an input signal IN and a reference signal (not shown in FIG. 1). As shown in FIG. 1, the PLL circuit 10 includes a multiplier 100, a phase error detecting unit 102, a filter 104, an oscillator 106, and a phase error estimating module 108. The multiplier 100 adjusts the phase of the input signal IN according to a phase compensating signal PC the oscillator 106 generates in order to generate a compensated input signal CIN to the phase error detecting unit 102. The phase error detecting unit 102 calculates a phase error Φ between the compensated input signal CIN and a reference signal, and outputs the phase error Φ to the filter 104. The filter 104 adjusts the phase compensating signal PC the oscillator 106 generates according to the phase error Φ. Through the loop formed by the multiplier 100, the phase error detecting unit 102, the filter 104 and the oscillator 106, the PLL circuit 10 may calibrate the phase error Φ between the compensated input signal CIN and the reference signal.

In FIG. 1, the phase error estimating module 108 calculates a phase error of known data in the input signal IN as an estimated phase error Φ_{ES} inputted to the oscillator 106. The estimated phase error Φ_{ES} is used as an initial value for calibrating the phase error Φ of unknown data in the input signal IN to accelerate the calibration speed. However, when the length of known data for generating the estimated phase error Φ_{ES} is insufficient, the estimated phase error Φ_{ES} may deviate from the real phase error, and the calibration speed of the PLL circuit 10 is reduced. Therefore, there is a need for a solution for preventing the estimated phase error Φ_{ES} from deviating from the real phase error when the length of known data is insufficient.

### SUMMARY OF THE INVENTION

To solve the above issue, the present invention provides a phase calibration method capable of estimating a phase error of unknown data in an input signal according to a relationship between calculated phase errors of known data in the input signal, and an associated phase locked loop (PLL) circuit.

According to an aspect of the present invention, a phase calibration method for a PLL circuit in a wireless communication device is provided. The method includes: calculating a header phase error of a header sub-frame of a frame in an input signal and a pilot phase error of a pilot sub-frame of the frame, wherein the header sub-frame and the pilot sub-frame are known data; generating an estimated phase error according to a relationship between the header phase error and the pilot phase error; generating a phase compensating signal according to the estimated phase error and a filtered signal; adjusting the input signal according to the phase compensating signal to generate a compensated input signal; detecting a phase error between a data sub-frame corresponding to the pilot sub-frame in the compensated input signal and a reference signal; and generating the filtered signal according to the phase difference.

According to another aspect of the present invention, a PLL circuit for a wireless communication system is provided. The PLL circuit includes: a phase error estimating module, calculating a header phase error of a header sub-frame of a frame in an input signal and a pilot phase error of a pilot sub-frame of the frame, wherein the header sub-frame and the pilot sub-frame are known data; a phase error adjusting module, generating an estimated phase error according to a relationship between the header phase error and the pilot phase error; an oscillator, generating a phase compensating signal according to the estimated phase error and a filtered signal; a multiplying unit, adjusting the input signal according to the phase compensating signal to generate a compensated input signal; a phase error detecting unit, detecting a phase error between a data sub-frame corresponding to the pilot sub-frame in the compensated input signal and a reference signal; and a filter, generating the filtered signal according to the phase error.

The above and other aspects of the invention will become better understood with regard to the following detailed description of the embodiments. The following description is made with reference to the accompanying drawings.

### BRIEF DESCRIPTION OF THE DRAWINGS

FIG. 1 is a schematic diagram of a phase locked loop (PLL) circuit of the prior art;

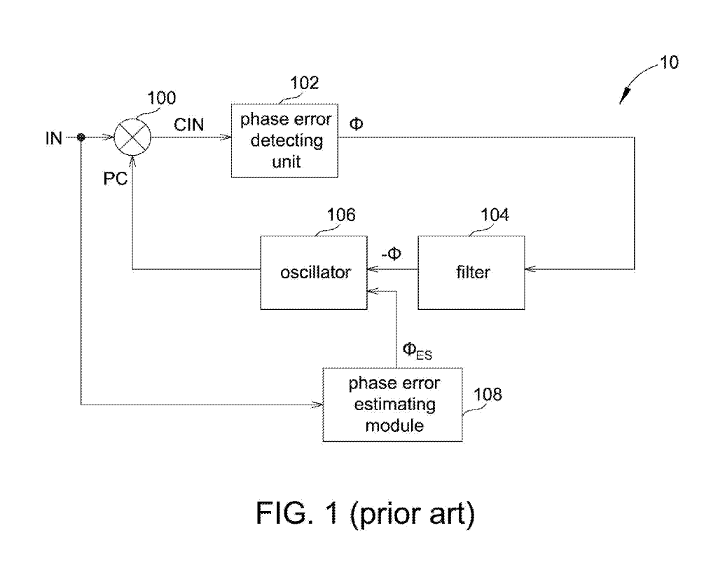

FIG. 2 is a schematic diagram of a PLL circuit according to an embodiment of the present invention;

FIG. 3 is a flowchart of a process according to an embodiment of the present invention;

FIG. 4 is a schematic diagram of a frame;

FIG. 5 is a schematic diagram of a phase error adjusting module according to an embodiment of the present invention;

FIG. 6 is a schematic diagram of a phase error adjusting module according to another embodiment of the present invention; and

FIG. 7 is a schematic diagram of a phase error adjusting module according to another embodiment of the present invention.

### DETAILED DESCRIPTION OF THE INVENTION

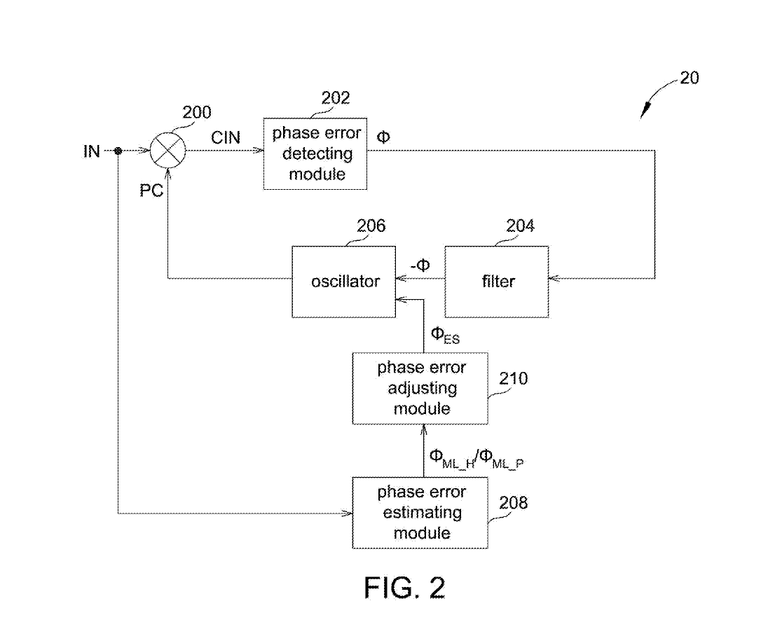

FIG. 2 shows a schematic diagram of a phase locked loop (PLL) circuit 20 according to an embodiment of the present invention. The PLL circuit 20 is for calibrating a phase error between an input signal IN and a reference signal (not shown in FIG. 2). As shown in FIG. 2, the PLL circuit 20 includes a multiplier 200, a phase error detecting unit 202, a filter 204, an oscillator 206, a phase error estimating module 208 and a phase error adjusting module 210. It should be noted that, operation details of the multiplier 200, the phase error detecting unit 202, the filter 204 and the oscillator 206 are respectively identical to those of the multiplier 100, the phase error detecting unit 102, the filter 104 and the oscillator 106 in the PLL circuit 10, and shall be omitted herein for brevity.

It should be noted that, the phase error detecting module 208 calculates a header phase error Φ_{ML}_{_}_{L} and a pilot phase error Φ_{ML}_{_}_{P} of known data in the input signal. Instead of being directly used as an estimated phase error Φ_{ES} inputted into the oscillator 206, the header phase error Φ_{ML}_{_}_{H} and the pilot phase error Φ_{ML}_{_}_{P} are first inputted to the phase error adjusting module 210 for adjustment. The phase error adjusting module 210 generates an initial value of the estimated phase error Φ_{ES} for calibrating the unknown data in the input signal IN according to a relationship between the header phase error Φ_{ML}_{_}_{H} and the pilot phase error Φ_{ML}_{_}_{P}. Compared to the PLL circuit 10, the estimated phase error Φ_{ES} adjusted through the phase error adjusting module 210 is closer to the phase error of the unknown data in the input signal IN, hence accelerating the calibration speed of the PLL circuit 20.

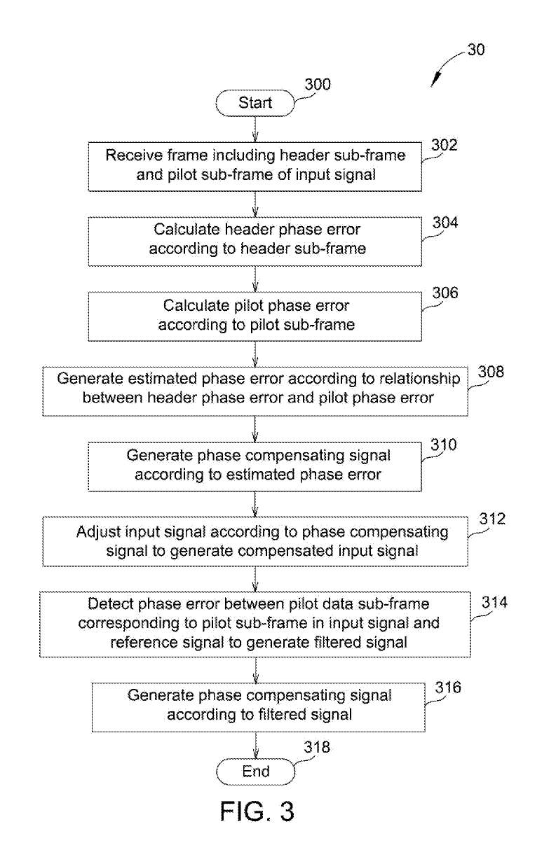

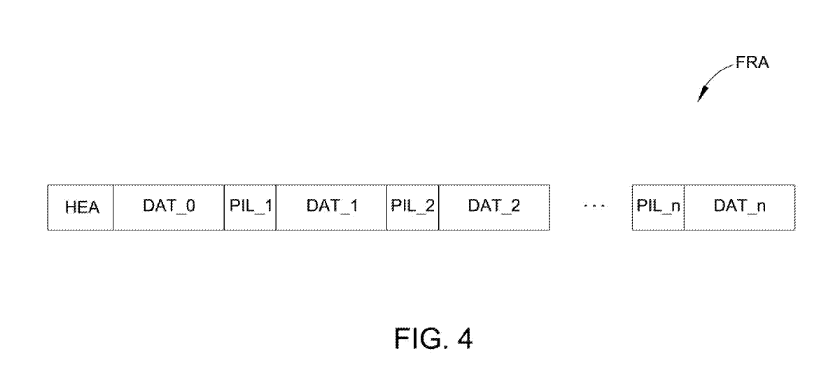

Operation details of the PLL circuit 20 are given with an example below. Referring to FIG. 3 and FIG. 4, FIG. 3 shows a flowchart of a process 30 of the PLL circuit 20, and FIG. 4 shows a schematic diagram of a frame FRA in the input signal IN. As shown in FIG. 4, the frame FRA includes a header sub-frame HEA, a plurality of pilot sub-frames PIL_1 to PIL_n, a data sub-frame DAT_0 corresponding to the header sub-frame HEA, and data sub-frames DAT_1 to DAT_n respectively corresponding to the pilot sub-frames PIL_1 to PIL_n. The header sub-frame HEA and the pilot sub-frames PIL_1 to PIL_n are known data, and a symbol length of the header sub-frame HEA is greater than symbol lengths of the pilot sub-frames PIL_1 to PIL_n. For example, when a wireless communication device operates in Digital Video Broadcasting-Satellite Second Generation (DVB-S2), the header sub-frame includes 90 symbols, and the pilot sub-frame includes 36 symbols.

In the process 30, the PLL circuit 20 first receives the input signal IN including the frame FRA (step 302). Because the header sub-frame HEA is known data (i.e., the phase error estimating module 208 learns in advance the data included in the header sub-frame HEA), the phase error estimating module 208 may directly calculate the phase error of the header sub-frame HEA as the header phase error Φ_{ML}_{_}_{H} to estimate the phase error of the data sub-frame DAT_0 subsequent to the header sub-frame HEA (step 304). For example, the phase error estimating module 208 may use a maximum likelihood (ML) method to calculate the header phase error Φ_{ML}_{_}_{H}. It should be noted that, the header sub-frame HEA is less susceptible to be affected by additive white Gaussian noise (AWGN) as it has a longer symbol length, and so the header phase error Φ_{ML}_{_}_{H} does not deviate much from the real phase error. Thus, the phase error adjusting module 210 may directly output the header phase error Φ_{ML}_{_}_{H} as the estimated phase error Φ_{ES}.

Using the estimated phase error Φ_{ES}, the PLL circuit 20 starts calibrating the phase difference of the data sub-frame DAT_0. More specifically, the oscillator 206 generates a phase compensating signal PC according to the estimated phase error Φ_{ES}, to cause the multiplier 206 to adjust the phase of the input signal IN to generate a compensated input signal CIN. Next, the phase error detecting unit 202 detects the phase error Φ between the data sub-frame DAT_0 in the compensated input signal CIN and the reference signal to cause the filter 204 to generate a corresponding filtered signal (−Φ). The oscillator 206 then adjusts the phase compensating signal PC according to the filtered signal (−Φ) to reduce the phase error Φ between the data sub-frame DAT_0 in the compensated input signal CIN and the reference signal.

Similarly, since the pilot sub-frame PIL_1 is also known data, the phase error estimating module 208 may directly calculate the phase error of the pilot sub-frame PIL_1 as the pilot phase error Φ_{MP}_{_}_{L} to estimate the phase error of the data sub-frame DAT_1 (i.e., the pilot sub-frame) subsequent to the pilot sub-frame PIL_1 (step 306). It should be noted that, the pilot sub-frame PIL_1 is more susceptible to be affected by noise as it has a shorter symbol length, in a way that the pilot phase error Φ_{ML}_{_}_{P} may deviate too much from the real phase error and so the calibration speed of PLL circuit is lowered.

To solve the above issue, the phase error adjusting module 210 generates the estimated phase error Φ_{ES} according to the relationship between the header phase error Φ_{ML}_{_}_{H} and the pilot phase error Φ_{ML}_{_}_{P} (step 308). In one embodiment, when a difference between the header phase error Φ_{ML}_{_}_{H} and the pilot phase error Φ_{ML}_{_}_{P} is smaller than an error threshold γ (|Φ_{ML}_{_}_{P1}|−|Φ_{ML}_{_}_{H}|<γ, γ<0), the phase error adjusting module 210 determines that the pilot phase error Φ_{ML}_{_}_{P} does not deviate too much from the real phase error, and directly outputs the pilot phase error Φ_{ML}_{_}_{P} as the estimated phase error Φ. When the difference between the header phase error Φ_{ML}_{_}_{H} and the pilot phase error Φ_{ML}_{_}_{P} exceeds the error threshold γ (|Φ_{ML}_{_}_{P1}|−|Φ_{ML}_{_}_{H}|>γ, γ<0), the phase error adjusting module 210 determines that the pilot phase error Φ_{ML}_{_}_{P} deviates too much from the real phase error. In this case, the phase error detecting module 210 adjusts the pilot phase error Φ_{ML}_{_}_{P}, and outputs the adjusted pilot phase error Φ_{ML}_{_}_{P} as the estimated phase error Φ_{ES}.

In one embodiment, the phase error adjusting module 210 calculates a product of the pilot phase error Φ_{ML}_{_}_{P} and a compensation coefficient CC as the estimated phase error Φ_{ES}, where the compensation coefficient CC is greater than 0 and smaller than 1 to alleviate the effect that the pilot phase error Φ_{ML}_{_}_{P} deviated too much from the real phase error has on calibrating the phase error Φ of the data sub-frame DAT_1, thereby increasing the calibration speed of the PLL circuit 20.

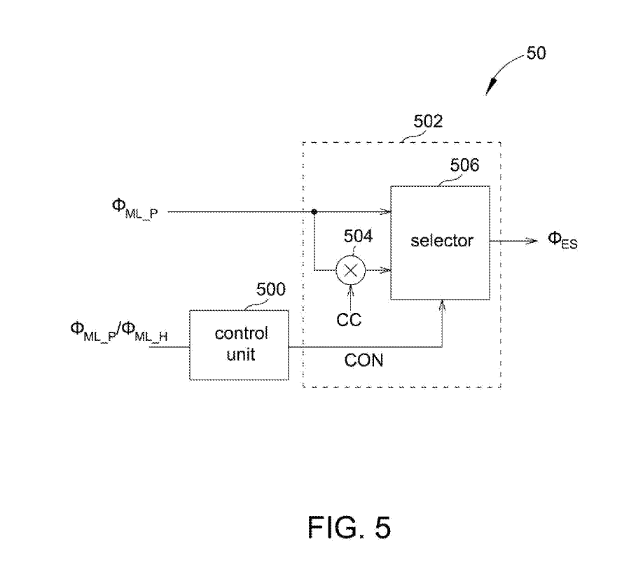

FIG. 5 shows a block diagram of a phase error adjusting module 50 according to an embodiment of the present invention. As shown in FIG. 5, the phase error adjusting module 50 includes a control unit 500 and an operation unit 502. The control unit 500 generates a control signal CON according to a relationship between the header phase error Φ_{ML}_{_}_{H} and the pilot phase error Φ_{ML}_{_}_{P}. The operation unit 502 generates the estimated phase error Φ according to the control signal CON. In this embodiment, the operation unit 502 includes a multiplier 504 and a selector 506. The multiplier 504 outputs a product of the pilot phase error Φ_{ML}_{_}_{P} and the compensation coefficient CC to the selector 506, which outputs the pilot phase error Φ_{ML}_{_}_{P} or the product of the pilot phase error Φ_{ML}_{_}_{P} and the compensation coefficient CC as the estimated phase error Φ according to the control signal CON. In one embodiment, the control unit 500 includes a storage unit for storing the header phase error Φ_{ML}_{_}_{H}, and generates the control signal CON according to a difference between the header phase error Φ_{ML}_{_}_{H} and the pilot phase error Φ_{ML}_{_}_{P} in the same frame when the pilot phase error Φ_{ML}_{_}_{P} is obtained. More specifically, when it is determined that the difference between header phase error Φ_{ML}_{_}_{H} and the pilot phase error Φ_{ML}_{_}_{P} in the same frame is smaller than the error threshold γ, the control unit 500 generates the control signal CON to cause the selector 506 to output the pilot phase error Φ_{ML}_{_}_{P} as the estimated phase error Φ_{ES}; when it is determined that the difference between header phase error Φ_{ML}_{_}_{H} and the pilot phase error Φ_{ML}_{_}_{P} in the same frame is greater than the error threshold γ, the control unit 500 generates the control signal CON to cause the selector 506 to output the product of the pilot phase error Φ_{ML}_{_}_{P} and the compensation coefficient CC as the estimated phase error Φ_{ES}.

In another embodiment, the phase error adjusting module 210 directly outputs a previously outputted estimated phase error Φ_{ES} (i.e., a previous estimated phase error Φ_{ES}_{_}_{PRE}) as the estimated phase error Φ_{ES}. This is because time differences among the data sub-frames DAT_0 to DAT_n in the same frame FRA are small, and so the phase errors among the data sub-frames DAT_0 to DAT_n in the same frame FRA are expectantly close to one another. It should be noted that, in this embodiment, when it is determined that the difference between the header phase error Φ_{ML}_{_}_{H} and the pilot phase error Φ_{ML}_{_}_{P} is smaller than the error threshold γ, the phase error adjusting module 210 stores the pilot phase error Φ_{ML}_{_}_{P} as the previous estimated phase error Φ_{ES}_{_}_{PRE}.

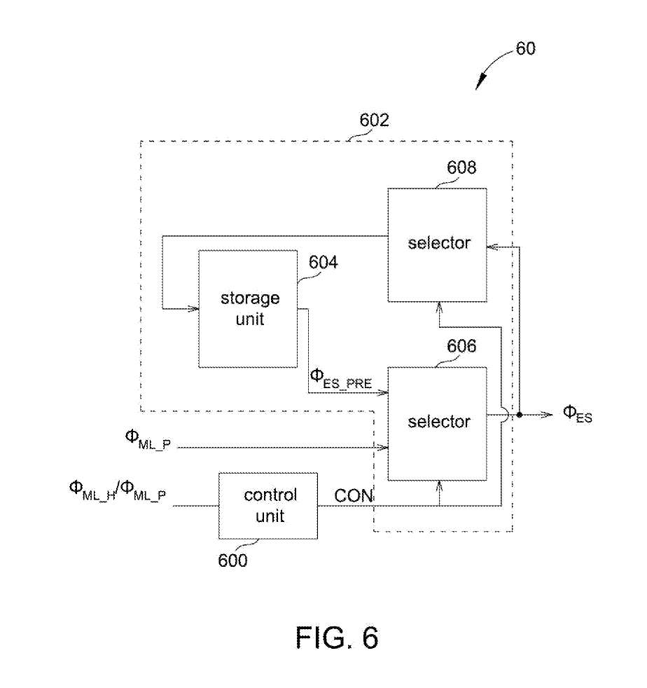

FIG. 6 shows a block diagram of a phase error adjusting module 60 according to an embodiment of the present invention. As shown in FIG. 6, the phase error adjusting module 60 includes a control unit 600 and an operation unit 602. The control unit 600 generates a control signal CON according to a relationship between the header phase error Φ_{ML}_{_}_{H} and the pilot phase error Φ_{ML}_{_}_{P}. The operation unit 602 generates the estimated phase error Φ_{ES} according to the control signal CON. In this embodiment, the operation unit 602 includes a storage unit 604, and selectors 606 and 608. The storage unit 604 stores the previous estimated phase error Φ_{ES}_{_}_{PRE}. The selector 606 selects one of the pilot phase error Φ_{ML}_{_}_{P} and the previous estimated phase error Φ_{ES}_{_}_{PRE} as the estimated phase error Φ_{ES} according to the control signal CON. The selector 608 determines whether to store the estimated phase error Φ_{ES} to the storage unit 604 according to the control signal CON.

More specifically, when it is determined that the difference between header phase error Φ_{ML}_{_}_{H} and the pilot phase error Φ_{ML}_{_}_{P} in the same frame is smaller than the error threshold γ, the control unit 600 generates the control signal CON to cause the selector 606 to output the pilot phase error Φ_{ML}_{_}_{P} as the estimated phase error Φ_{ES}, and to cause the selector 608 to output the estimated phase error Φ_{ES} to the storage unit 604 to store the current estimated phase error Φ_{ES} as the previous estimated phase error D_{ES}_{_}_{PRE}; when it is determined that the difference between header phase error Φ_{ML}_{_}_{H} and the pilot phase error Φ_{ML}_{_}_{P} in the same frame is greater than the error threshold γ, the control unit 600 generates the control signal CON to cause the selector 606 to output the previous estimated phase error Φ_{ES}_{_}_{PRE} stored in the storage unit 604 as the estimated phase error Φ_{ES}, and to cause the selector 60 to stop outputting the estimated phase error Φ_{ES} to the storage unit 604.

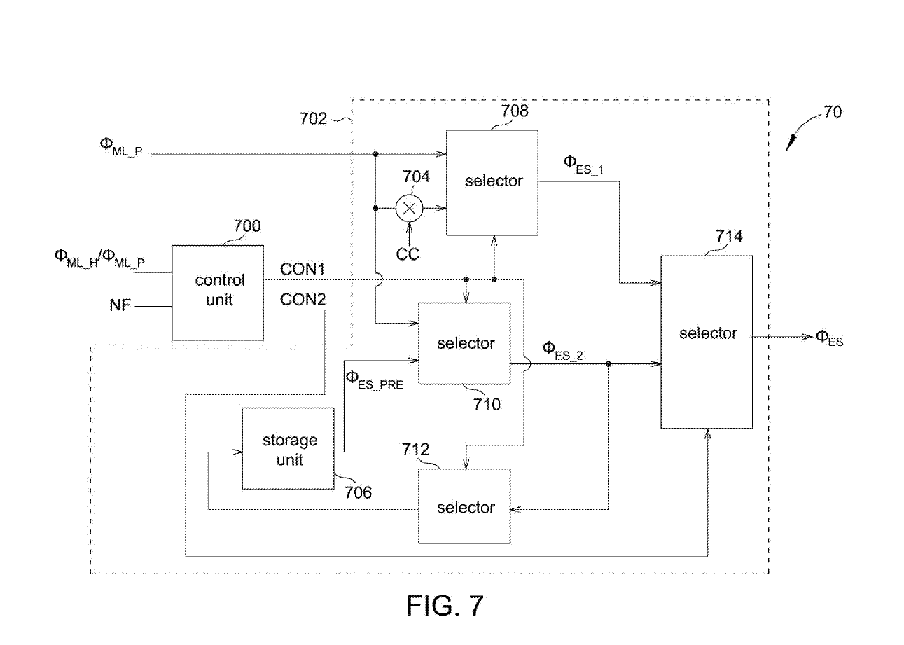

FIG. 7 shows a block diagram of a phase error adjusting module 70 according to an embodiment of the present invention. As shown in FIG. 7, the phase error adjusting module 70 includes a control unit 700 and an operation unit 702. The control unit 700 generates a control signal CON1 according to a relationship between the header phase error Φ_{ML}_{_}_{H} and the pilot phase error Φ_{ML}_{_}_{P}. The operation unit 702 generates the estimated phase error Φ_{ES} according to the control signal CON1. In this embodiment, the operation unit 702 includes a multiplier 704, a storage unit 706, and selectors 708, 710, 712 and 714. In this embodiment, operation details of the control unit 700, the multiplier 704 and the selector 708 are similar to those of the control unit 500, the multiplier 504 and the selector 506 in FIG. 5; operation details of the control unit 700, the storage unit 706 and the selectors 710 and 712 are similar to those of the control unit 600, the storage unit 604 and the selectors 606 and 608 in FIG. 6. For brevity, these repeated details are omitted herein.

In this embodiment, the control unit 700 further generates a control signal CON2 according to a noise indication signal NF to cause the selector 714 to output one of first estimated phase error Φ_{ES}_{_}₁ and second estimated phase error Φ_{ES}_{_}₂ as the estimated phase error Φ_{ES} according to the control signal CON2. More specifically, when the noise indication signal NF determines that a noise variance within a predetermined time interval is smaller than a variance threshold, the control unit 700 generates the control signal CON2 to control the selector 714 to output the first estimated phase error Φ_{ES}_{_}₁ as the estimated phase error Φ_{ES}; when the noise indication signal NF determines that the noise variance within the predetermined time interval is greater than the variance threshold, the control unit 700 generates the control signal CON2 to control the selector 714 to output the second estimated phase error Φ_{ES}_{_}₂ as the estimated phase error Φ_{ES}.

After the estimated phase error Φ_{ES} is generated according to the relationship between the header phase error Φ_{ML}_{_}_{H} and the pilot phase error Φ_{ML}_{_}_{P}, the oscillator 206 generates the phase compensating signal PC according to the estimated phase error Φ_{ES} (step 310), to cause the multiplier 200 to adjust the phase of the data sub-frame DAT_1 in the input signal IN to further generate the compensated input signal CIN (step 312). Next, the phase error detecting unit 202 detects the phase error Φ between the data sub-frame DAT_1 in the compensated input signal CIN and the reference signal to cause the filter 204 to generate the corresponding filtered signal (−Φ) (step 314). The oscillator 206 then generates the phase compensating signal PC according to the filtered signal (−Φ) (step 316) to reduce the phase error Φ between the data sub-frame DAT_2 in the compensated input signal CIN and the reference signal.

By repeating steps 306 to 316, the PLL circuit 20 may adjust the estimated phase errors Φ_{ES} respectively serving as initial values for calibrating the data sub-frames DAT_1 to DAT_n according to the relationships between header phase error Φ_{ML}_{_}_{H} and the pilot phase error Φ_{ML}_{_}_{P}, so as to increase the speed of calibrating the phase errors of the data sub-frames DAT_1 to DAT_n for the PLL circuit 20.

While the invention has been described by way of example and in terms of the embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A phase calibration method, applied to a phase locked loop (PLL) circuit in a wireless communication device, comprising:
calculating a header phase error of a header sub-frame of a frame in the input signal and a pilot phase error of a pilot sub-frame of the frame, wherein the header sub-frame and the pilot sub-frame are known data;
generating an estimated phase error according to a relationship between the header phase error and the pilot phase error;
generating a phase compensating signal according to the estimated phase error and a filtered signal;
adjusting the input signal according to the phase compensating signal to generate a compensated input signal;
detecting a phase error between a data sub-frame corresponding to the pilot sub-frame in the compensated input signal and a reference signal; and
generating the filtered signal according to the phase error.

2. The phase calibration method according to claim 1, wherein the step of generating the estimated phase error according to the relationship between the header phase error and the pilot phase error comprises:
outputting the pilot phase error as the estimated phase error when a difference between the header phase error and the pilot phase error is smaller than an error threshold.

3. The phase calibration method according to claim 1, wherein the step of generating the estimated phase error according to the relationship between the header phase error and the pilot phase error comprises:
adjusting the pilot phase error to generate the estimated phase error when a difference between the header phase error and the pilot phase error is greater than an error threshold.

4. The phase calibration method according to claim 3, wherein the step of adjusting the pilot phase error to generate the estimated phase error when the difference between the header phase error and the pilot phase error is greater than the error threshold comprises:
according to a determination result indicating that the difference between the header phase error and the pilot phase error is greater than the error threshold, calculating a product of the pilot phase error and a compensation coefficient as the estimated phase error, wherein the compensation coefficient is greater than 0 and smaller than 1.

5. The phase calibration method according to claim 4, wherein the step of calculating the product of the pilot phase error and the compensation coefficient as the estimated phase error according to the determination result indicating that the difference between the header phase error and the pilot phase error is greater than the error threshold comprises:
according to the determination result indicating that the difference between the header phase error and the pilot phase error is greater than the error threshold, and a determination result indicating that a phase noise variance is smaller than a variance threshold, calculating the product of the pilot phase error and the compensation coefficient as the estimated phase error.

6. The phase calibration method according to claim 1, wherein the step of generating the estimated phase error according to the relationship between the header phase error and the pilot phase error comprises:
according to a determination result indicating that a difference between the header phase error and the pilot phase error is greater than an error threshold, utilizing a previous estimated phase error as the estimated phase error.

7. The phase calibration method according to claim 6, wherein the step of utilizing the previous estimated phase error as the estimated phase error according to the determination result indicating that the difference between the header phase error and the pilot phase error is greater than the error threshold comprises:
according to the determination result indicating that the difference between the header phase error and the pilot phase error is greater than the error threshold, and a determination result indicating that a phase noise variance is greater than a variance threshold, utilizing the previous estimated phase error as the estimated phase error.

8. The phase calibration method according to claim 6, further comprising:
according to a determination result indicating that the difference between the header phase error and the pilot phase error is smaller than the error threshold, storing the pilot phase error as the previous estimated phase error.

9. A phase locked loop (PLL) circuit for a wireless communication system, comprising:
a phase error estimating module, calculating a header phase error of a header sub-frame of a frame in an input signal and a pilot phase error of a pilot sub-frame of the frame, wherein the header sub-frame and the pilot sub-frame are known data;
a phase error adjusting module, generating an estimated phase error according to a relationship between the header phase error and the pilot phase error;
an oscillator, generating a phase compensating signal according to the estimated phase error and a filtered signal;
a multiplying unit, adjusting the input signal according to the phase compensating signal to generate a compensated input signal;
a phase error detecting unit, detecting a phase error between a data sub-frame corresponding to the pilot sub-frame in the compensated input signal and a reference signal; and
a filter, generating the filtered signal according to the phase error.

10. The PLL circuit according to claim 9, wherein the phase error adjusting module comprises:
a control unit, generating a first control signal according to the header phase error and the pilot phase error; and
an operation unit, generating the estimated phase error according to the first control signal.

11. The PLL circuit according to claim 10, wherein the operation unit comprises:
a multiplier, calculating a product of the pilot phase error and a compensation coefficient as an adjusted pilot phase error; and
a selector, outputting one of the pilot phase error and the adjusted pilot phase error as the estimated phase error.

12. The PLL circuit according to claim 10, wherein the operation unit comprises:
a storage unit, storing a previous estimated phase error;
a first selector, outputting one of the pilot phase error and the previous estimated phase error as the estimated phase error according to the first control signal; and
a second selector, storing the estimated phase error to the storage unit according to the first control signal.

13. The PLL circuit according to claim 10, wherein the control unit further generates a second control signal according to a noise indication signal, and the operation unit comprises:
a multiplier, calculating a product of the pilot phase error and a compensation coefficient as an adjusted pilot phase error;
a storage unit, storing a previous estimated phase error;
a first selector, outputting one of the pilot phase error and the adjusted pilot phase error as a first phase error according to the first control signal;
a second selector, outputting one of the pilot phase error and the previous estimated phase error as a second phase error according to the first control signal;
a third selector, storing the estimated phase error to the storage unit according to the first control signal; and
a fourth selector, outputting one of the first phase error and the second phase error as the estimated phase error according to the second control signal.
